(19) United States
(12) Patent Application Publication
(10) Pub. No.: US 2011/0102980 A1
(43) Pub. Date: May 5, 2011

(54) DIGITAL PHOTO FRAME TO PICTURE FRAME ADAPTER

(75) Inventors: William R. Tittle, Indianapolis, IN (US); Kwai Nam Chan, Ma On Shan (HK)

(73) Assignee: Audiovox Corporation, Hauppauge, NY (US)

(21) Appl. No.: 12/613,245

(22) Filed: Nov. 5, 2009

(51) Int. Cl. H05K 5/00

(52) U.S. Cl. 361/679.01

(57) ABSTRACT

An adapter for a picture frame allows a digital photo frame (DPF) to be mounted into a picture frame. A lock mechanism on the adapter engages into a catch of the DPF, and mounting pockets on the adapter engage with mounting tabs of the DPF, to lock the adapter to the DPF. A flange on the adapter is configured to engage the interior sides of the picture frame. The adapter allows the DPF to be attached to picture frames of various sizes, and picture frames utilizing various back attachment methods.

### BACKGROUND

1. Technical Field

The present disclosure relates to an adapter for a picture frame that allows a digital photo frame (DPF) to be mounted into a picture frame.

2. Discussion of Related Art

Digital photo frames (DPFs) are often sold with picture frames built directly into the DPFs. Alternatively, DPFs may be sold with uniquely sized, removable picture frames that are specifically designed to fit the DPFs they are sold with. Because these removable frames are not standard sized picture frames, customers cannot use standard retail frames with DPFs. Rather, customers are limited to the styles and colors of the frames offered by the DPF manufacturers. Although it is possible to have a custom sized picture frame made to fit a particular DPF, such customization can be expensive and inconvenient.

Therefore, a need exists for a device that allows a DPF to be attached to a standard retail picture frame.

### BRIEF SUMMARY

According to an embodiment of the present disclosure, an adapter for a picture frame comprises a lock mechanism configured to engage into a catch of a digital photo frame (DPF), to engage a first edge of the adapter to a first end of the DPF. The adapter further comprises mounting pockets configured to engage with mounting tabs of the DPF, to engage a second edge of the adapter to a second end of the DPF. The adapter further comprises a flange extending from the edges of the adapter, configured to engage the picture frame.

The lock mechanism of the adapter may comprise a spring-loaded locker, and the spring-loaded locker may comprise at least one of a guide pin, a spring, locker stops, or a removal slot.

The outside dimension of the flange may be different from the outside dimension of the DPF.

The adapter and the picture frame may attach via latches on the picture frame, latches on the adapter, bendable tabs on the picture frame, spring clips in enclosed channels of a sectional frame, or tension plates on the picture frame.

According to an embodiment of the present disclosure, a DPF and picture frame system comprises a DPF and an adapter. The adapter is configured to attach to the DPF and a picture frame, and the adapter comprises a flange extending from edges of the adapter, configured to engage the picture frame.

The DPF and picture frame system may further include a mat. The mat may comprise an opening for an infrared (IR) sensor on the DPF, and may be constructed from paper or vinyl.

The DPF and picture frame system may further include a transparent material. The transparent material may comprise one of glass or plexiglass.

### BRIEF DESCRIPTION OF THE SEVERAL VIEWS OF THE DRAWINGS

Preferred embodiments of the present disclosure will be described below in more detail, with reference to the accompanying drawings:

FIG. 1 illustrates an overview of the digital photo frame (DPF) and picture frame system, according to an embodiment of the present disclosure.

FIG. 2 illustrates the mat of the DPF and picture frame system, according to an embodiment of the present disclosure.

FIG. 3 illustrates attachment of the DPF to the adapter, according to an embodiment of the present disclosure.

FIG. 4 illustrates attachment of the DPF to the adapter, according to an embodiment of the present disclosure.

FIG. 5 illustrates the mounting pockets of the adapter, according to an embodiment of the present disclosure.

FIG. 6 illustrates the mounting tabs of the DPF, according to an embodiment of the present disclosure.

FIG. 7 illustrates attachment of the DPF to the adapter, according to an embodiment of the present disclosure.

FIG. 8 illustrates the spring-loaded locker of the adapter configured to engage into the catch of the DPF, according to an embodiment of the present disclosure.

FIG. 9 illustrates the spring-loaded locker of the adapter, according to an embodiment of the present disclosure.

FIG. 10 illustrates the spring-loaded locker of the adapter, according to an embodiment of the present disclosure.

FIG. 11 illustrates the guide pin and locker stops of the spring-loaded locker of the adapter, according to an embodiment of the present disclosure.

FIG. 12 illustrates the flange of the adapter, according to an embodiment of the present disclosure.

FIG. 13 illustrates the adapter attaching to a picture frame via latches on the picture frame, according to an embodiment of the present disclosure.

FIG. 14A illustrates the adapter attaching to a picture frame via a slot and latch attachment system, according to an embodiment of the present disclosure.

FIG. 14B illustrates the slot of the picture frame in FIG. 14A.

FIG. 15A illustrates a picture frame utilizing a rabbet joint and slot attachment method.

FIG. 15B is an enlarged view of the rabbet joint and slot attachment method illustrated in FIG. 15A.

FIG. 16 illustrates the adapter attaching to a picture frame via tension plates and screws, according to an embodiment of the present disclosure.

FIG. 17 illustrates the adapter attaching to a metal sectional frame utilizing metal spring clips in enclosed metal channels, according to an embodiment of the present disclosure.

FIG. 18A illustrates the adapter attaching to a picture frame via tension plates and screws, according to an embodiment of the present disclosure.

FIG. 18B is an enlarged view of the tension plates and screws illustrated in FIG. 18A.

FIG. 19A illustrates the adapter attaching to a picture frame via a slot and latch attachment system, according to an embodiment of the present disclosure.

FIG. 19B is an enlarged view of the slot and latch attachment system illustrated in FIG. 19A.

### DETAILED DESCRIPTION

Exemplary embodiments of the present invention now will be described more fully hereinafter with reference to the accompanying drawings. This invention, may however, be embodied in many different forms and should not be construed as limited to the embodiments set forth herein.

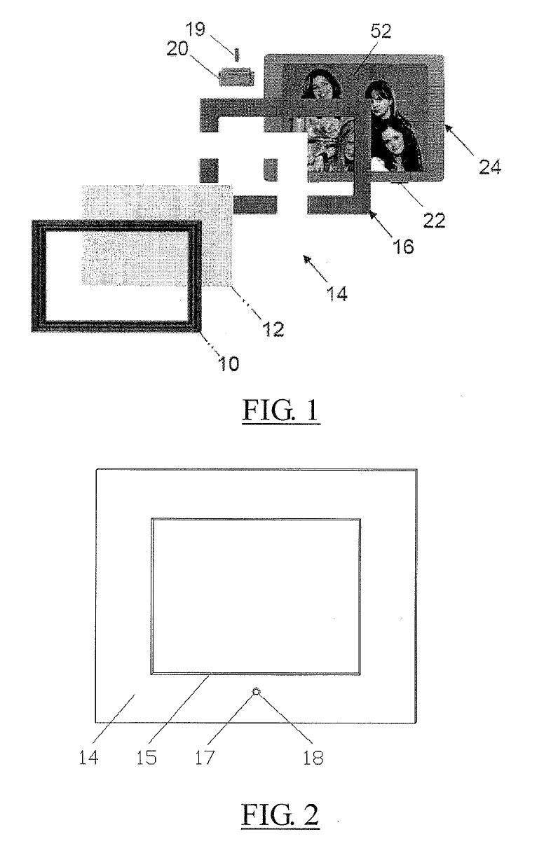

FIG. 1 illustrates an overview of the digital photo frame (DPF) and picture frame system according to an embodiment of the present disclosure. The DPF to picture frame adapter (hereinafter referred to as the “adapter”) 16 attaches to both the DPF 24 and the picture frame 10, holding the DPF 24 and the picture frame 10 together. The adapter 16 may be constructed from, but is not limited to, a strong molded plastic material, such as, for example, High Impact Polystyrene (HIPS) or Acrylonitrile Butadiene Styrene (ABS). A lock mechanism is utilized to lock the DPF 24 to the adapter 16. In an embodiment, the lock mechanism comprises a spring-loaded locker 20 having a compression spring 19. When engaged, the compression spring 19 applies pressure to the spring-loaded locker 20, causing the locker 20 to lock the DPF 24 to the adapter 16. The picture frame 10 may be a retail picture frame chosen by the user. Picture frames of various sizes can be used with the adapter 16. In an embodiment, a transparent material 12 (e.g., glass, plexiglass) between the picture frame 10 and a mat 14 holds the mat 14 in place and allows for clear viewing of the DPF screen 52.

FIG. 2 illustrates the mat 14 according to an embodiment of the present disclosure. The mat 14 is located between the transparent material 12 and the adapter 16, and hides the adapter 16 from the view of the user. The mat 14 is held in place against the adapter 16 by the transparent material 12. The dimensions of the mat correspond to the size of the picture frame 10 and the screen size of the DPF 24. For example, the outside dimensions of the mat 14 will be smaller than the size of the picture frame 10, allowing the mat 14 to fit within the picture frame 10, and an opening in the center of the mat 14 will match the screen size of the DPF 24, allowing for viewing of the DPF screen 52. As shown in FIG. 2, the mat 14 may include an infrared (IR) sensor opening 17 and an IR lens 18 to accommodate a DPF 24 having an IR sensor for remote operation. Although FIG. 2 shows the IR sensor opening 17 and IR lens 18 located towards the bottom of the mat 14, it is to be understood that the IR sensor opening 17 and IR lens 18 may be located anywhere on the mat 14 to accommodate different locations of the IR sensor on the DPF 24. The mat 14 may be constructed using various materials, including, but not limited to, paper and vinyl. The thickness of the mat 14 may be modified such that it is compatible with different types of picture frames 10. For example, a thicker mat (e.g., approximately 0.05 inches) may be used with picture frames originally designed to be used with a mat, while a thinner mat (e.g., approximately 0.02 inches) may be used with picture frames that have not been designed to be used with a mat. Thick mats may include a beveled edge 15 on the opening in the center of the mat.

### Attachment of DPF to Adapter

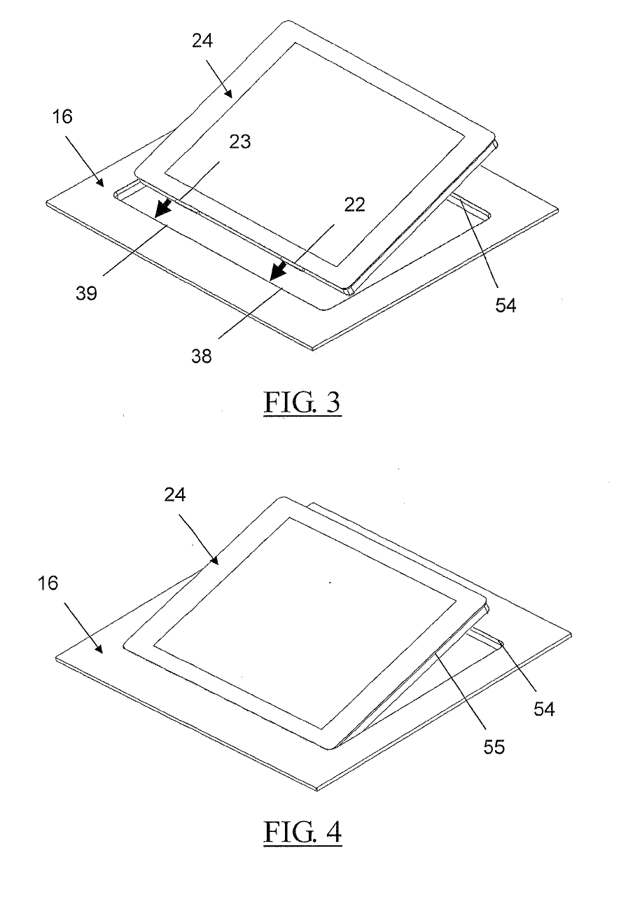

FIGS. 3 and 4 illustrate attachment of the DPF 24 to the adapter 16 according to an embodiment of the present disclosure. The DPF 24 is inserted into an opening near the center of the adapter 16. A chamfer 54 at the edge of the opening of the adapter 16 corresponds to a chamfer 55 on the DPF flange 64, and mounting tabs 22 and 23 of the DPF 24 correspond to mounting pockets 38 and 39 of the adapter 16. This arrangement allows the DPF 24 to be guided and centered into the opening of the adapter 16 as shown in FIG. 4.

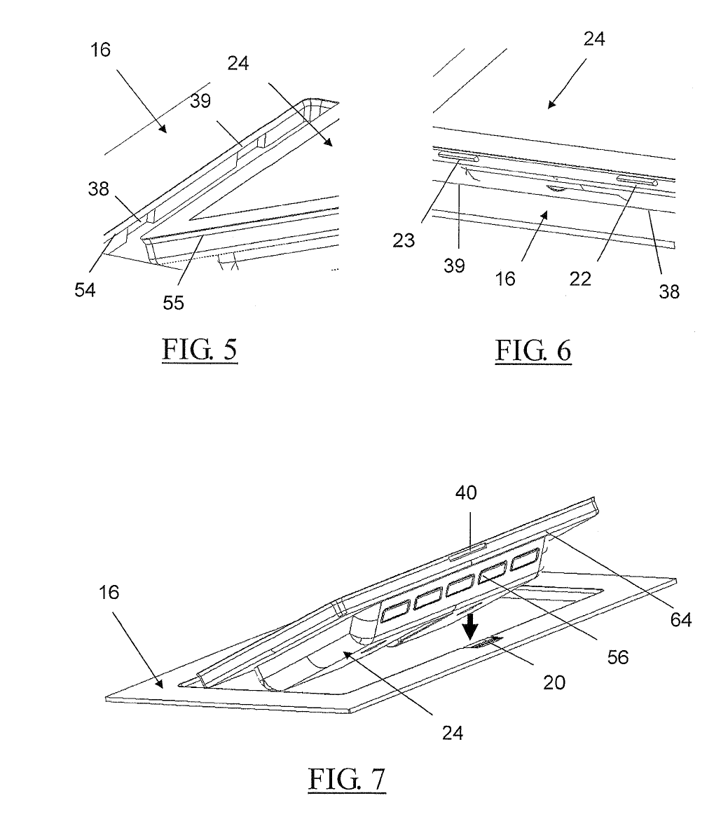

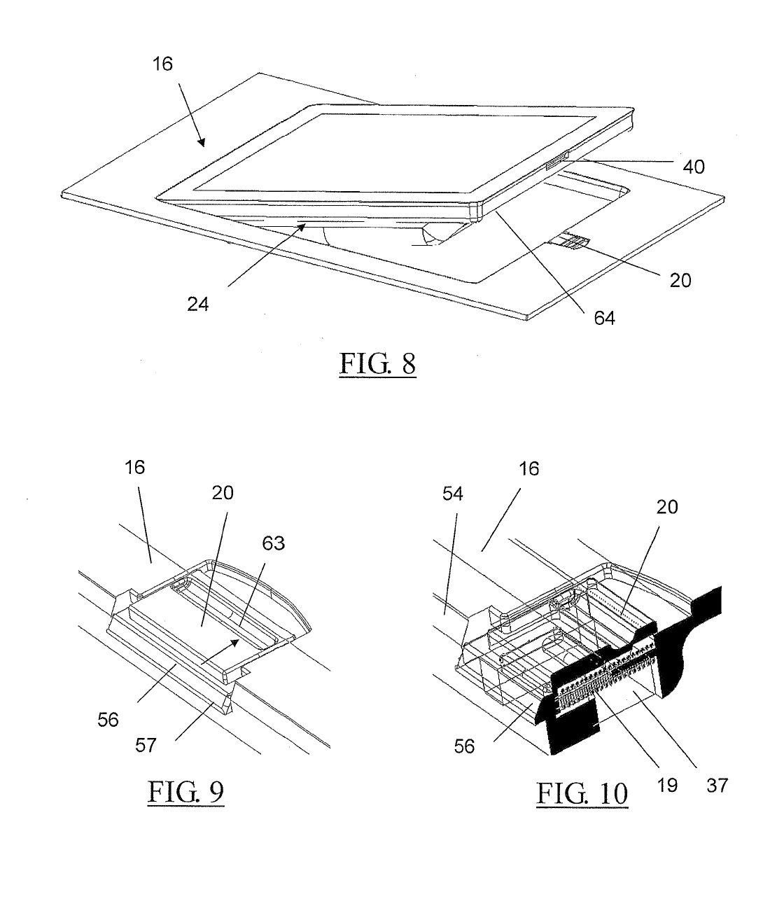

FIGS. 5-8 provide a more detailed view of the attachment of the DPF 24 to the adapter 16 according to an embodiment of the present disclosure. As shown in FIG. 5, mounting pockets 38 and 39 are located on the inside edge of the opening of the adapter 16, below the adapter chamfer 54. Mounting tabs 22 and 23, located on the DPF flange 64 below the DPF chamfer 55, engage the mounting pockets 38 and 39, as depicted in FIG. 6. The mounting tabs 22 and 23 on the DPF 24 and the mounting pockets 38 and 39 on the adapter 16 lock the bottom end of the DPF 24 to the bottom edge of the adapter 16, as shown in FIG. 4. A catch 40 on the DPF 24 and the spring-loaded locker 20 on the adapter 16 engage into each other to lock the top end of the DPF 24 to the top edge of the adapter 16, as shown in FIGS. 7 and 8. The combinations of the DPF flange 64 and the adapter chamfer 54, mounting pockets 38 and 39 and mounting tabs 22 and 23, and the spring-loaded locker 20 and the catch 40 lock the DPF 24 to the adapter 16. Although the exemplary embodiment describes the mounting pockets 38 and 39 on the bottom edge of the adapter 16 and the spring-loaded locker 20 on the top edge of the adapter 16, it is to be appreciated that the mounting pockets 38 and 39 and the spring-loaded locker 20 may be disposed on any opposing edges of the adapter 16. The respective locations of the mounting tabs 22 and 23 and catch 40 of the DPF 24 may similarly be located on any opposing ends of the DPF 24, corresponding to the respective locations of the mounting pockets 38 and 39 and the spring-loaded locker 20 on the adapter 16.

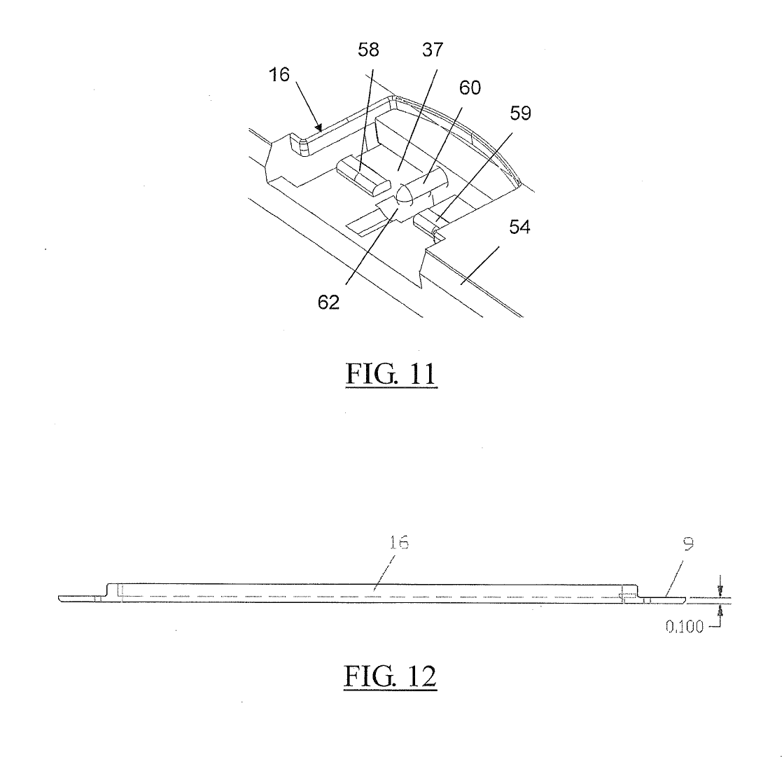

FIGS. 9-11 illustrate the spring-loaded locker 20 according to an embodiment of the present disclosure. As shown in the embodiment in FIG. 9, the spring-loaded locker 20 may be located on the top edge of the adapter 16, however the locker 20 may also be located on other edges of the adapter 16 according to other embodiments. Upon insertion of the DPF 24 into the adapter 16, a chamfer 56 on the locker 20 contacts the DPF flange 64. As the DPF 24 is lowered further into the adapter 16, the DPF flange 64 pushes the locker 20 open until a leading edge 57 of the locker 20 engages into the catch 40 on the DPF 24. Once engaged, the compression spring 19, which is located within the locker cavity 37 of the locker 20 as shown in FIG. 10, pushes the locker 20 closed, locking the DPF 24 to the adapter 16. FIG. 11 shows the compression spring's guide pin 60, as well as locker stops 58 and 59, according to an embodiment of the present disclosure. The guide pin 60 provides support for the compression spring 19, and locker stops 58 and 59 prevent the compression spring 19 from pushing the locker 20 too far out of the locker cavity 37. In another embodiment, the DPF 24 may be detached from the adapter 16 by utilizing a removal slot 63 on the locker 20. For example, a user may detach the DPF 24 from the adapter 16 by inserting a screwdriver or a fingertip into the removal slot 63 and pushing the locker 20 open by sliding it in the direction of the arrow shown in FIG. 9.

### Attachment of Adapter to Picture Frame

To attach the DPF 24 to a picture frame 10, the original back plate of the picture frame 10 is replaced with the adapter 16. An 8×10 inch picture frame may be selected for use with the adapter 16 because 8×10 inch frames are compatible with DPFs having various screen sizes (e.g., 7-9 inches). Suitable dimensions for an adapter 16 that can accommodate most 8×10 inch picture frames include, but are not limited to, outside dimensions of approximately 7.969×9.969 inches and a flange 9 thickness of approximately 0.100 inches, as illustrated in FIG. 12. The flange 9 of the adapter 16 is configured to engage the interior sides of the picture frame 10. Although an 8×10 inch picture frame may be desirable because it is compatible with a number of DPFs having various screen sizes, the adapter 16 is not limited to use with an 8×10 inch frame. The adapter 16 may be used with a variety of picture frames utilizing different back attachment methods, as discussed below.

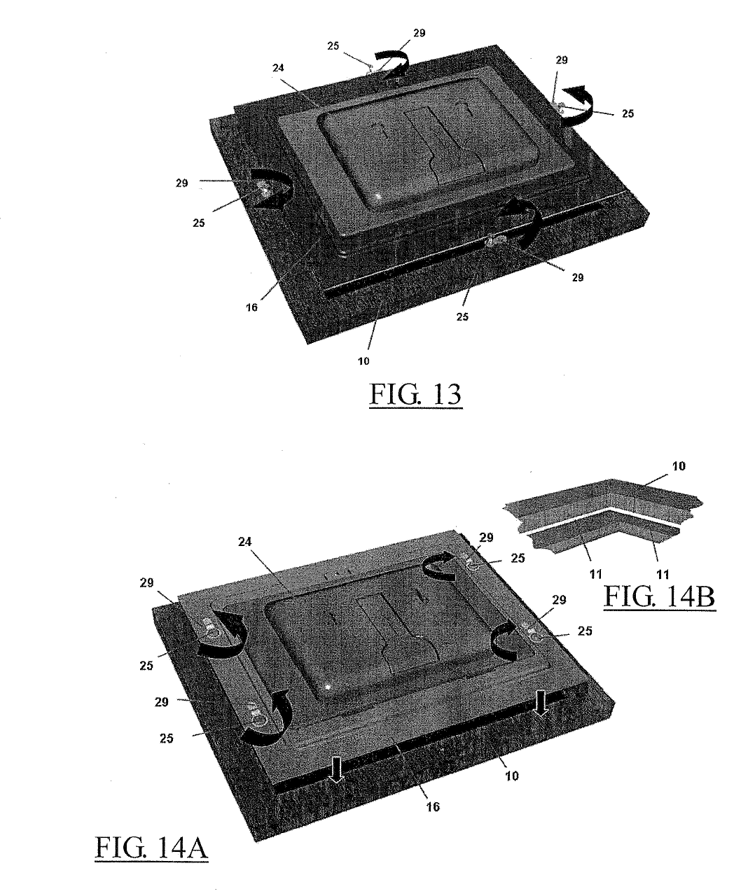

In an embodiment of the present disclosure, the adapter 16 is designed to be attached to a picture frame 10 that utilizes a rotating latches attachment system. This attachment method is illustrated in FIG. 13. In this embodiment, the original back plate of the picture frame 10 is removed. Latches 29 on the picture frame 10 are rotated to an open position and the adapter 16, which may already be attached to the DPF 24, is inserted into the picture frame 10. The latches 29 on the picture frame 10 are then rotated over a portion of the adapter 16 to hold the picture frame 10 to the adapter 16.

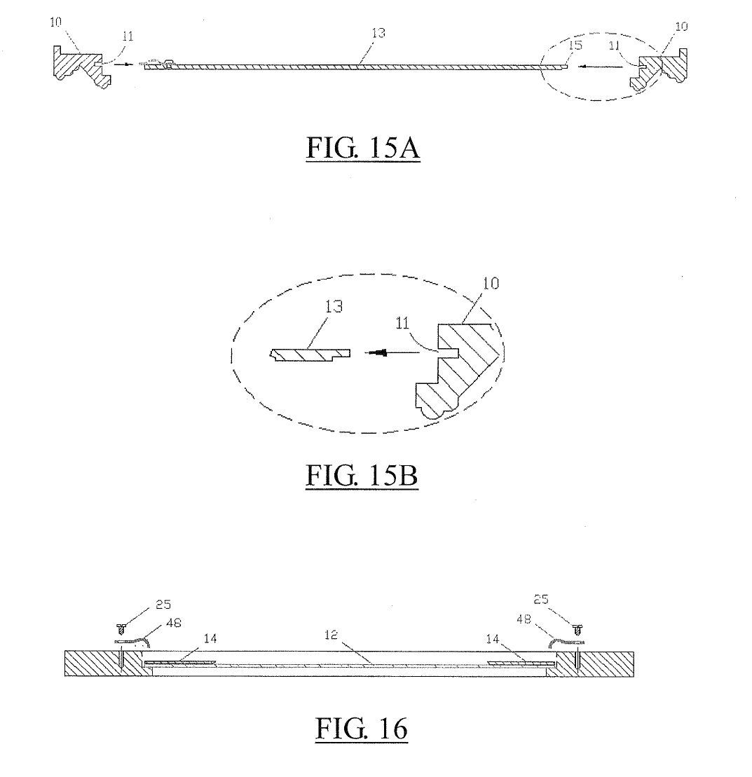

In an embodiment of the present disclosure, the adapter 16 is designed to be attached to a picture frame 10 that utilizes a slot and latch attachment system. This attachment method is illustrated in FIGS. 14A and 14B. In this embodiment, the original back plate of the picture frame 10 is removed. Latches 29 are attached to the adapter 16. The latches 29 may be removable and may be attached to the adapter 16 by, for example, screws 25 or nails. The latches 29 are rotated to an open position and the adapter 16, which may already be attached to the DPF 24, is inserted into the picture frame 10. The latches 29 are then rotated to engage in a slot 11 located on the inside of the picture frame 10. This slot 11 is illustrated in FIG. 14B. The adapter 16 in this embodiment may also be used to replace an original back plate of a picture frame 10 that is attached via rabbet joints 15 fitting into a slot 11 of the picture frame 10, as depicted in FIGS. 15A and 15B.

In an embodiment of the present disclosure, the adapter 16 is designed to be attached to a picture frame 10 that utilizes staples or bendable tabs (e.g., bendable metal tabs) for attachment. In this embodiment, the staples or bendable tabs are bent open and the original back plate of the picture frame 10 is removed. The adapter 16, which may already be attached to the DPF 24, is inserted into the picture frame 10 and the staples or bendable tabs are bent closed, securing the adapter 16 to the picture frame 10. In an embodiment, the staples or bendable tabs may be replaced with screws 25 and tension plates 48, as depicted in FIG. 16.

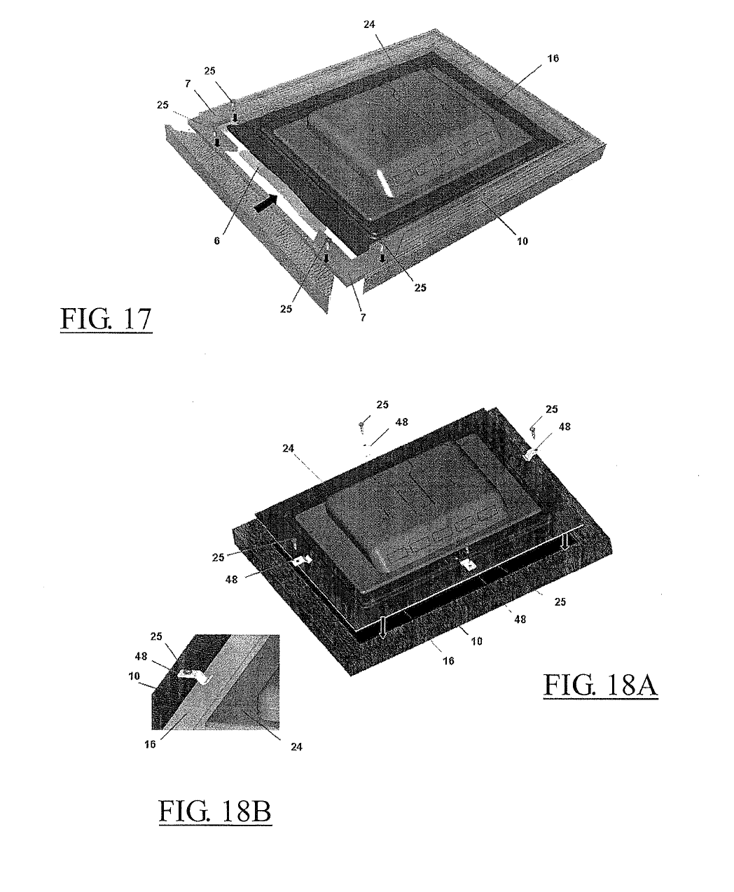

In an embodiment of the present disclosure, the adapter 16 is designed to be attached to a metal sectional picture frame 10 that utilizes metal spring clips 6 in enclosed metal channels. This attachment method is illustrated in FIG. 17. In this embodiment, sections of the frame 10 are disconnected, the original back plate of the frame 10 is removed, and the adapter 16, which may already be attached to the DPF 24, is inserted into a slot of the frame 10. Metal spring clips 6 are placed between the frame 10 and the adapter 16 to secure the adapter 16 to the frame 10, and the sections of the frame 10 are reconnected. The frame may utilize metal plates 7 and screws 25 to connect the sections of the frame 10 to each other.

In an embodiment of the present disclosure, the adapter 16 is designed to be attached to a picture frame 10 with an open back utilizing tension plates 48 and screws 25. This attachment method is illustrated in FIGS. 18A and 18B. In this embodiment, the adapter 16, which may already be attached to the DPF 24, is inserted into the picture frame 10. The tension plates 48 are then connected to the picture frame 10 by, for example, screws 25 or nails. Once attached to the picture frame 10, the tension plates 48 apply pressure to the adapter 16, securing the adapter 16 to the picture frame 10.

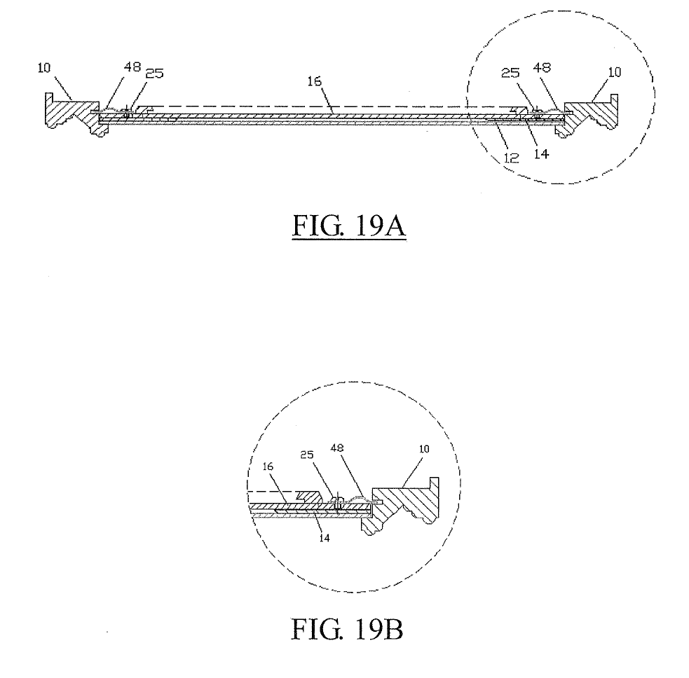

Picture frames utilizing different attachment methods may have different sized back plates. For example, back plates having latches, staples or bendable tabs, metal spring clips (e.g., metal sectional frames), and tension plates and screws (e.g., open back frames) may be smaller than a back plate that is attached to a picture frame 10 via rabbet joints 15 fitting within a slot 11 of the picture frame 10. In this example, the size difference is due to the addition of the rabbet joints 15, as illustrated in FIGS. 15A and 15B. Thus, while the smaller back plates may measure approximately 7.969×9.969 inches, the larger back plate with rabbet joints 15 may measure approximately 8×10.157 inches. In an embodiment of the present disclosure, an adapter 16 may be designed with the smaller dimensions (e.g., approximately 7.9×9.9 inches) and latches 29 in place of the rabbet joints 15, as illustrated in FIGS. 19A and 19B. This configuration allows the adapter 16 to be used with picture frames utilizing different attachment methods having different sized back plates.

Although exemplary embodiments of the present invention have been described hereinabove, it should be understood that the present invention is not limited to these embodiments, but may be modified by those skilled in the art without departing from the spirit and scope of the present invention, as defined by the appended claims.

What is claimed is:

1. An adapter for a picture frame, comprising:
a lock mechanism configured to engage into a catch of a digital photo frame (DPF), to engage a first edge of the adapter to a first end of the DPF;
mounting pockets configured to engage with mounting tabs of the DPF, to engage a second edge of the adapter to a second end of the DPF; and
a flange extending from the edges of the adapter, configured to engage the picture frame.

2. The adapter of claim 1, wherein the lock mechanism comprises a spring-loaded locker.

3. The adapter of claim 2, wherein the spring-loaded locker comprises at least one of a guide pin, locker stops, or a removal slot.

4. The adapter of claim 1, wherein the adapter is constructed from plastic.

5. The adapter of claim 4, wherein the plastic comprises one of High Impact Polystyrene (HIPS) or Acrylonitrile Butadiene Styrene (ABS).

6. The adapter of claim 1, wherein the outside dimension of the flange is different from the outside dimension of the DPF.

7. The adapter of claim 6, wherein the outside dimension of the flange is one of about 7.9×9.9, 4.9×6.9, or 3.9×5.9 inches.

8. The adapter of claim 1, wherein the adapter and the picture frame attach via latches on the picture frame.

9. The adapter of claim 1, wherein the adapter and the picture frame attach via latches on the adapter.

10. The adapter of claim 9, wherein the latches are attached to the adapter with one of screws or nails.

11. The adapter of claim 1, wherein the adapter and the picture frame attach via bendable tabs on the picture frame.

12. The adapter of claim 1, wherein the picture frame comprises a sectional frame, and the adapter and the sectional frame attach via spring clips in enclosed channels of the sectional frame.

13. The adapter of claim 1, wherein the adapter and the picture frame attach via tension plates on the picture frame.

14. The adapter of claim 13, wherein the tension plates are attached to the picture frame with one of screws or nails.

15. A digital photo frame (DPF) and picture frame system, comprising:
a DPF;
an adapter configured to attach to the DPF and a picture frame, wherein the adapter comprises a flange extending from edges of the adapter, configured to engage the picture frame.

16. The DPF and picture frame system of claim 15, further comprising a mat.

17. The DPF and picture frame system of claim 16, wherein the mat comprises an opening for an infrared (IR) sensor on the DPF.

18. The DPF and picture frame system of claim 16, wherein the mat is constructed from one of paper or vinyl.

19. The DPF and picture frame system of claim 15, further comprising a transparent material.

20. The DPF and picture frame system of claim 19, wherein the transparent material comprises one of glass or plexiglass.
